(19) United States
(12) Patent Application Publication
(10) Pub. No.: US 2020/0194463 A1
(43) Pub. Date: Jun. 18, 2020

(54) INVERTER AND GOA CIRCUIT

(71) Applicant: Wuhan China Star Optoelectronics Technology Co., Ltd., Wuhan (CN)

(72) Inventor: Hualun YU, Wuhan (CN)

(73) Assignee: Wuhan China Star Optoelectronics Technology Co., Ltd., Wuhan (CN)

(21) Appl. No.: 16/471,579

(22) PCT Filed: Nov. 1, 2018
(86) PCT No.: PCT/CN2018/113253

§ 371 Date: Jun. 20, 2019

(30) Foreign Application Priority Data
Sep. 29, 2018 (CN) 201811144369.4

(51) Int. Cl. H01L 27/12; G09G 3/20

(52) U.S. Cl. CPC H01L 27/1214; G09G 2320/0209; G09G 2310/0267; G09G 3/20

(57) ABSTRACT

An inverter includes: a first thin film transistor including: a first substrate; at least one first buffer layer formed on the first substrate; and a first polysilicon layer formed on a part of the at least one first buffer layer; and a second thin film transistor including: a second substrate; at least one second buffer layer formed on the second substrate; and a second polysilicon layer formed on a part of the at least one second buffer layer. The first thin film transistor further includes a first light shielding layer formed between the first substrate and the at least one first buffer layer, and/or the second thin film transistor further includes a second light shielding layer formed between the second substrate and the at least one second buffer layer. A GOA circuit is further provided.

### BACKGROUND

### Field

The present disclosure relates to a display device, and more particularly to an inverter used for a display device and a GOA circuit.

### Background

Gate driver on array (GOA) circuits refer to that thin film transistors (TFT) used for controlling scan lines are manufactured on peripheries of display areas of display panels by processes of the display panels. The GOA circuits includes basic logical circuits, for example, inverters (INV), transfer gates (TG), NAND gates, NOR gates and so on.

Please refer to FIG. 1. FIG. 1 illustrates that an inverter outputs a scan signal to a scan line G.

The inverter includes a P-type thin film transistor P and an N-type thin film transistor N. A gate of the P-type thin film transistor P and a gate of the N-type thin film transistor N are electrically coupled to an input terminal IN. A source of the P-type thin film transistor P is electrically coupled to a direct-current voltage source VGH having a high voltage level. A source of the N-type thin film transistor N is electrically coupled to a direct-current voltage source VGL having a low voltage level. A drain of the P-type thin film transistor P and a drain of the N-type thin film transistor N are electrically coupled to the scan line G.

When a signal having a high voltage level is inputted to the input terminal IN, the P-type thin film transistor P is not turned on and the N-type thin film transistor N is turned on. The scan line G is at the low voltage level (electrically coupled to the direct-current voltage source VGL).

When a signal having a low voltage level is inputted to the input terminal IN, the P-type thin film transistor P is turned on and the N-type thin film transistor N is not turned on. The scan line G is at the high voltage level (electrically coupled to the direct-current voltage source VGH).

When electrical characteristics of the P-type thin film transistor P become worse, a threshold voltage Vth is shifted toward a positive value. Accordingly, a Vgs of the P-type thin film transistor P approaches the threshold voltage Vth, and a turned-on current of the P-type thin film transistor P is increased. A conduction path exists between the direct-current voltage source VGH having the high voltage level and the direct-current voltage source VGL having the low voltage level. Finally, the scan line G approaches 0 voltage, and a thin film transistor electrically coupled to a pixel is slowly turned on. A leakage current is increased, and thus crosstalk phenomenon occurs in a display panel.

Consequently, there is a need to solve the above-mentioned problems in the prior art.

### SUMMARY OF THE DISCLOSURE

When electrical characteristics of a P-type thin film transistor become worse, a threshold voltage is shifted toward a positive value. Accordingly, a thin film transistor electrically coupled to a pixel is slowly turned on. A leakage current is increased, and thus crosstalk phenomenon occurs in a display panel.

An objective of the present disclosure is to provide an inverter and a GOA circuit capable of solving the problems in the prior art.

To solve the above problems, an inverter provided by the present disclosure is used for a GOA circuit. The inverter includes: a first thin film transistor including: a first substrate; at least one first buffer layer formed on the first substrate; a first polysilicon layer formed on a part of the at least one first buffer layer; a first gate insulating layer formed on the at least one first buffer layer and the first polysilicon layer; and a first gate formed on the first gate insulating layer; and a second thin film transistor including: a second substrate; at least one second buffer layer formed on the second substrate; a second polysilicon layer formed on a part of the at least one second buffer layer; a second gate insulating layer formed on the at least one second buffer layer and the second polysilicon layer; and a second gate formed on the first gate insulating layer. The first thin film transistor further includes a first light shielding layer formed between the first substrate and the at least one first buffer layer, and/or the second thin film transistor further includes a second light shielding layer formed between the second substrate and the at least one second buffer layer. The first gate is electrically coupled to an input terminal, and the second gate is electrically coupled to the input terminal. The first thin film transistor further includes a first source and a first drain, the first source is electrically coupled to a first direct-current voltage source, and the first drain is electrically coupled to an output terminal. The second thin film transistor further includes a second source and a second drain, the second source is electrically coupled to a second direct-current voltage source, and the second drain is electrically coupled to the output terminal. When a signal having a high voltage level is inputted to the input terminal, the output terminal outputs a signal having a low voltage level.

In one embodiment, the first thin film transistor is a P-type thin film transistor.

In one embodiment, the second thin film transistor is an N-type thin film transistor.

To solve the above problems, an inverter provided by the present disclosure is used for a GOA circuit. The inverter includes: a first thin film transistor including: a first substrate; at least one first buffer layer formed on the first substrate; a first polysilicon layer formed on a part of the at least one first buffer layer; a first gate insulating layer formed on the at least one first buffer layer and the first polysilicon layer; and a first gate formed on the first gate insulating layer; and a second thin film transistor including: a second substrate; at least one second buffer layer formed on the second substrate; a second polysilicon layer formed on a part of the at least one second buffer layer; a second gate insulating layer formed on the at least one second buffer layer and the second polysilicon layer; and a second gate formed on the first gate insulating layer. The first thin film transistor further includes a first light shielding layer formed between the first substrate and the at least one first buffer layer, and/or the second thin film transistor further includes a second light shielding layer formed between the second substrate and the at least one second buffer layer.

In one embodiment, the first gate is electrically coupled to an input terminal, and the second gate is electrically coupled to the input terminal.

In one embodiment, the first thin film transistor further includes a first source and a first drain, the first source is electrically coupled to a first direct-current voltage source, and the first drain is electrically coupled to an output terminal. The second thin film transistor further includes a second source and a second drain, the second source is electrically coupled to a second direct-current voltage source, and the second drain is electrically coupled to the output terminal.

In one embodiment, the first thin film transistor is a P-type thin film transistor.

In one embodiment, the second thin film transistor is an N-type thin film transistor.

A GOA circuit provided by the present disclosure includes a plurality of inverters. Each of the inverters includes: a first thin film transistor including: a first substrate; at least one first buffer layer formed on the first substrate; a first polysilicon layer formed on a part of the at least one first buffer layer; a first gate insulating layer formed on the at least one first buffer layer and the first polysilicon layer; and a first gate formed on the first gate insulating layer; and a second thin film transistor including: a second substrate; at least one second buffer layer formed on the second substrate; a second polysilicon layer formed on a part of the at least one second buffer layer; a second gate insulating layer formed on the at least one second buffer layer and the second polysilicon layer; and a second gate formed on the first gate insulating layer. The first thin film transistor further includes a first light shielding layer formed between the first substrate and the at least one first buffer layer, and/or the second thin film transistor further includes a second light shielding layer formed between the second substrate and the at least one second buffer layer.

In one embodiment, the first gate is electrically coupled to an input terminal, and the second gate is electrically coupled to the input terminal.

In one embodiment, the first thin film transistor further includes a first source and a first drain, the first source is electrically coupled to a first direct-current voltage source, and the first drain is electrically coupled to an output terminal. The second thin film transistor further includes a second source and a second drain, the second source is electrically coupled to a second direct-current voltage source, and the second drain is electrically coupled to the output terminal.

In one embodiment, the first thin film transistor is a P-type thin film transistor.

In one embodiment, the second thin film transistor is an N-type thin film transistor 1.

Compared to the prior art, in the inverter of the GOA circuit of the present disclosure, the light shielding layer is disposed in at least one of the P-type thin film transistor and the N-type thin film transistor. The light shielding layer can reduce the leakage current, thereby avoiding the crosstalk phenomenon of the display panel.

### BRIEF DESCRIPTION OF THE DRAWINGS

FIG. 1 illustrates that an inverter outputs a scan signal to a scan line.

FIG. 2 illustrates a top view of an inverter of a GOA circuit in accordance with an embodiment of the present disclosure.

FIG. 3 illustrates a sectional view along a line AA′ in FIG. 2.

FIG. 4 illustrates a sectional view along a line BB′ in FIG. 2.

### DETAILED DESCRIPTION OF THE PREFERRED EMBODIMENTS

Hereinafter, exemplary embodiments of the present disclosure will be described with reference to the accompanying drawings for illustrating specific embodiments which can be carried out by the present disclosure.

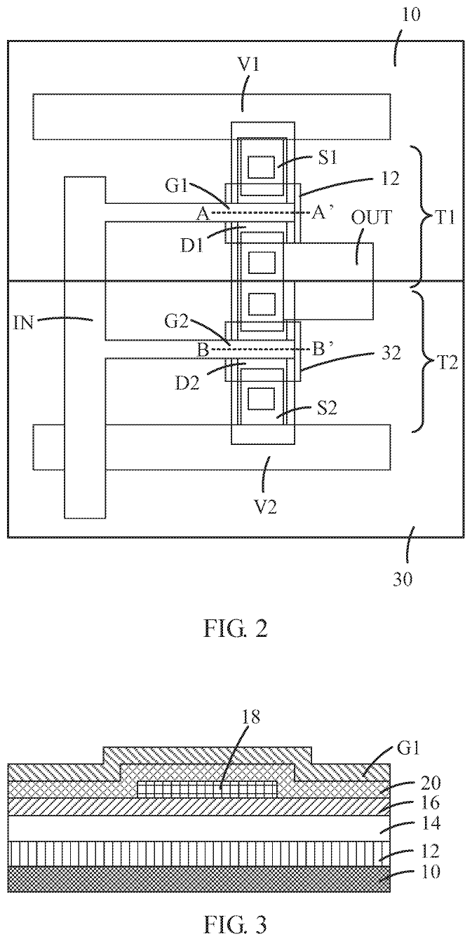

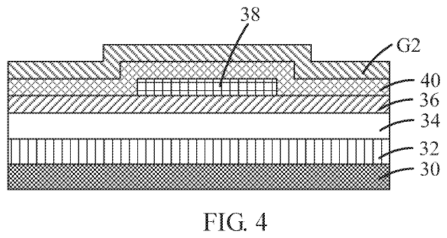

Please refer to FIG. 2 to FIG. 4. FIG. 2 illustrates a top view of an inverter of a GOA circuit in accordance with an embodiment of the present disclosure. FIG. 3 illustrates a sectional view along a line AA′ in FIG. 2. FIG. 4 illustrates a sectional view along a line BB′ in FIG. 2.

The GOA circuit includes a plurality of inverters and is disposed on a display panel. In detail, the GOA circuit is disposed on a periphery of a display area of the display panel.

Each of the inverters includes a first thin film transistor T1 and a second thin film transistor T2.

The first thin film transistor T1 includes a first substrate 10, a first light shielding layer 12, at least one first buffer layer (two first buffer layers 14 and 16 are shown in FIG. 3), a first polysilicon layer 18, a first gate insulating layer 20, a first gate G1, a first source S1 and a first drain D1.

The first substrate 10 is an array substrate of the display panel. The first substrate 10 may be but is not limited to a glass substrate or a flexible substrate.

The first light shielding layer 12 is formed on the first substrate 10.

The first buffer layer 14 is formed on the first light shielding layer 12. The first buffer layer 14 may be a silicon oxide layer or a silicon nitride layer.

The first buffer layer 16 is formed on the first buffer layer 14. The first buffer layer 16 may be a silicon oxide layer or a silicon nitride layer.

The first polysilicon layer 18 is formed on a part of the first buffer layer 16.

The first gate insulating layer 20 is formed on the first buffer layer 16 and the first polysilicon layer 18.

The first gate G1 is formed on the first gate insulating layer 20 and electrically coupled to an input terminal IN.

Positions of forming the first source S1 and the first drain D1 are the same as those in the prior art and thus are not repeated herein.

The first source S1 is electrically coupled to a first direct-current voltage source V1. The first drain D1 is electrically coupled to an output terminal OUT. The output terminal OUT is electrically coupled to a scan line of the display panel.

The second thin film transistor T2 includes a second substrate 30, a second light shielding layer 32, at least one second buffer layer (two second buffer layers 34 and 36 are shown in FIG. 4), a second polysilicon layer 38, a second gate insulating layer 40, a second gate G2, a second source S2 and a second drain D2.

The second substrate 30 is the array substrate of the display panel. The second substrate 30 may be but is not limited to a glass substrate or a flexible substrate. The first substrate 10 and the second substrate 30 are the array substrate of the display panel.

The second light shielding layer 32 is formed on the second substrate 30.

The second buffer layer 34 is formed on the second light shielding layer 32. The second buffer layer 34 may be a silicon oxide layer or a silicon nitride layer.

The second buffer layer 36 is formed on the second buffer layer 34. The second buffer layer 36 may be a silicon oxide layer or a silicon nitride layer.

The second polysilicon layer 38 is formed on a part of the second buffer layer 36.

The second gate insulating layer 40 is formed on the second buffer layer 36 and the second polysilicon layer 38.

The second gate G2 is formed on the second gate insulating layer 40 and electrically coupled to the input terminal IN.

Positions of forming the second source S2 and the second drain D2 are the same as those in the prior art and thus are not repeated herein.

The second source S2 is electrically coupled to a second direct-current voltage source V2. The second drain D2 is electrically coupled to the output terminal OUT.

It can be understood from FIG. 3 and FIG. 4 that the first thin film transistor T1 and the second thin film transistor T2 have similar structures.

A feature of the inverter of the GOA circuit of the present disclosure is that at least one of the first thin film transistor T1 and the second thin film transistor T2 has a light shielding layer. In the present embodiment, the first thin film transistor T1 includes the first light shielding layer 12 disposed therein, and the second thin film transistor T2 includes the second light shielding layer 32 disposed therein. In another embodiment, only the first thin film transistor T1 includes the first light shielding layer 12 disposed therein, and the second thin film transistor T2 does not include the second light shielding layer 32 disposed therein. In yet another embodiment, only the second thin film transistor T2 includes the second light shielding layer 32 disposed therein, and the first thin film transistor T1 does not include the first light shielding layer 12 disposed therein.

Furthermore, in the present embodiment, the first thin film transistor T1 is formed as a P-type thin film transistor by doping a trivalent element. The trivalent element, for example, may be but is not limited to boron.

The second thin film transistor T2 is formed as an N-type thin film transistor by doping a pentavalent element. The pentavalent element, for example, may be but is not limited to phosphorus.

The feature of the inverter of the GOA circuit of the present disclosure is that the first light shielding layer 12 or the second light shielding layer 32 is disposed. The first light shielding layer 12 is configured to shield the first thin film transistor T1 (P-type thin film transistor). When a threshold voltage of the first thin film transistor T1 (P-type thin film transistor) is shifted toward a positive value, a turned-on current of the first thin film transistor T1 (P-type thin film transistor) is smaller because the first light shielding layer 12 shields the first thin film transistor T1 (P-type thin film transistor). Accordingly, the first thin film transistor T1 (P-type thin film transistor) is not turned on.

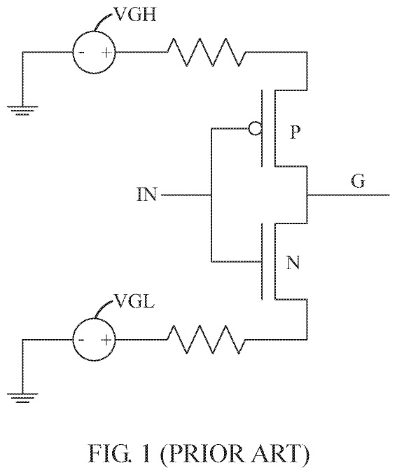

As such, when a signal having a high voltage level is inputted to the first gate G1 of the first thin film transistor T1 (P-type thin film transistor), a situation that the first thin film transistor T1 (P-type thin film transistor) is turned on because the threshold voltage is shifted toward the positive value does not occur. A scan signal inputted to the scan line is still the direct-current voltage source VGL having the low voltage level in FIG. 1. That is, when the signal having the high voltage level is inputted to the inverter, the inverter outputs a signal having a low voltage level. The inverter can implement a function of outputting the signal having the low voltage level normally. In detail, the first light shielding layer 12 can reduce a leakage current of the first thin film transistor T1 (P-type thin film transistor), thereby avoiding crosstalk phenomenon of the display panel.

Furthermore, the second light shielding layer 32 also can reduce a leakage current of the second thin film transistor T2 (N-type thin film transistor), thereby avoiding crosstalk phenomenon of the display panel.

In the inverter of the GOA circuit of the present disclosure, the light shielding layer is disposed in at least one of the P-type thin film transistor and the N-type thin film transistor. The light shielding layer can reduce the leakage current, thereby avoiding the crosstalk phenomenon of the display panel.

In summary, although the present disclosure has been provided in the preferred embodiments described above, the foregoing preferred embodiments are not intended to limit the present disclosure. Those skilled in the art, without departing from the spirit and scope of the present disclosure, may make modifications and variations, so the scope of the protection of the present disclosure is defined by the claims.

What is claimed is:

1. An inverter, used for a GOA circuit, the inverter comprising:
a first thin film transistor comprising:
a first substrate;
at least one first buffer layer formed on the first substrate;
a first polysilicon layer formed on a part of the at least one first buffer layer;
a first gate insulating layer formed on the at least one first buffer layer and the first polysilicon layer; and
a first gate formed on the first gate insulating layer; and
a second thin film transistor comprising:
a second substrate;
at least one second buffer layer formed on the second substrate;
a second polysilicon layer formed on a part of the at least one second buffer layer;
a second gate insulating layer formed on the at least one second buffer layer and the second polysilicon layer; and
a second gate formed on the first gate insulating layer,
wherein the first thin film transistor further comprises a first light shielding layer formed between the first substrate and the at least one first buffer layer, and/or
the second thin film transistor further comprises a second light shielding layer formed between the second substrate and the at least one second buffer layer,
the first gate is electrically coupled to an input terminal, and the second gate is electrically coupled to the input terminal,
the first thin film transistor further comprises a first source and a first drain, the first source is electrically coupled to a first direct-current voltage source, and the first drain is electrically coupled to an output terminal,
the second thin film transistor further comprises a second source and a second drain, the second source is electrically coupled to a second direct-current voltage source, and the second drain is electrically coupled to the output terminal,
when a signal having a high voltage level is inputted to the input terminal, the output terminal outputs a signal having a low voltage level.

2. The inverter of claim 1, wherein the first thin film transistor is a P-type thin film transistor.

3. The inverter of claim 1, wherein the second thin film transistor is an N-type thin film transistor.

4. An inverter, used for a GOA circuit, the inverter comprising:
a first thin film transistor comprising:
a first substrate;
at least one first buffer layer formed on the first substrate;
a first polysilicon layer formed on a part of the at least one first buffer layer;
a first gate insulating layer formed on the at least one first buffer layer and the first polysilicon layer; and
a first gate formed on the first gate insulating layer; and
a second thin film transistor comprising:
a second substrate;
at least one second buffer layer formed on the second substrate;
a second polysilicon layer formed on a part of the at least one second buffer layer;
a second gate insulating layer formed on the at least one second buffer layer and the second polysilicon layer; and
a second gate formed on the first gate insulating layer,
wherein the first thin film transistor further comprises a first light shielding layer formed between the first substrate and the at least one first buffer layer, and/or
the second thin film transistor further comprises a second light shielding layer formed between the second substrate and the at least one second buffer layer.

5. The inverter of claim 4, wherein the first gate is electrically coupled to an input terminal, and the second gate is electrically coupled to the input terminal.

6. The inverter of claim 4, wherein the first thin film transistor further comprises a first source and a first drain, the first source is electrically coupled to a first direct-current voltage source, and the first drain is electrically coupled to an output terminal,
the second thin film transistor further comprises a second source and a second drain, the second source is electrically coupled to a second direct-current voltage source, and the second drain is electrically coupled to the output terminal.

7. The inverter of claim 4, wherein the first thin film transistor is a P-type thin film transistor.

8. The inverter of claim 4, wherein the second thin film transistor is an N-type thin film transistor.

9. A GOA circuit, comprising a plurality of inverters, each of the inverters comprising:
a first thin film transistor comprising:
a first substrate;
at least one first buffer layer formed on the first substrate;
a first polysilicon layer formed on a part of the at least one first buffer layer;
a first gate insulating layer formed on the at least one first buffer layer and the first polysilicon layer; and
a first gate formed on the first gate insulating layer; and
a second thin film transistor comprising:
a second substrate;
at least one second buffer layer formed on the second substrate;
a second polysilicon layer formed on a part of the at least one second buffer layer;
a second gate insulating layer formed on the at least one second buffer layer and the second polysilicon layer; and
a second gate formed on the first gate insulating layer,
wherein the first thin film transistor further comprises a first light shielding layer formed between the first substrate and the at least one first buffer layer, and/or
the second thin film transistor further comprises a second light shielding layer formed between the second substrate and the at least one second buffer layer.

10. The GOA circuit of claim 9, wherein the first gate is electrically coupled to an input terminal, and the second gate is electrically coupled to the input terminal.

11. The GOA circuit of claim 9, wherein the first thin film transistor further comprises a first source and a first drain, the first source is electrically coupled to a first direct-current voltage source, and the first drain is electrically coupled to an output terminal,
the second thin film transistor further comprises a second source and a second drain, the second source is electrically coupled to a second direct-current voltage source, and the second drain is electrically coupled to the output terminal.

12. The GOA circuit of claim 9, wherein the first thin film transistor is a P-type thin film transistor.

13. The GOA circuit of claim 9, wherein the second thin film transistor is an N-type thin film transistor.
